(19) United States
(12) Patent Application Publication
(10) Pub. No.: US 2024/0426892 A1
(43) Pub. Date: Dec. 26, 2024

(54) Synchronization of data acquisition devices of an online monitoring system for monitoring an electrical distribution network through detection of zero crossings

(71) Applicant: NEXANS, Courbevoie (FR)

(72) Inventors: Moussa KAFAL, Les Ulis (FR); Samuel GRIOT, LYON (FR)

(21) Appl. No.: 18/673,294

(22) Filed: May 23, 2024

(30) Foreign Application Priority Data
May 25, 2023 (FR) 2305176

(51) Int. Cl. G01R 31/08

(52) U.S. Cl. CPC G01R 31/088; G01R 31/086

(57) ABSTRACT

An arrangement for synchronization between at least two data acquisition devices of an online monitoring system for monitoring an electrical distribution network, each located at a known point A or B in the network and configured to detect high-frequency events during data acquisition phases. During a first phase of estimating the period of the electrical signal travelling through the network, each data acquisition device samples the electrical signal travelling through the network and deduces therefrom an estimate T′_{A} or T′_{B} of the period of the electrical signal by detecting times of zero crossings of the sampled signal, which are locally timestamped by a timestamping means associated with each data acquisition device. One of the devices then sends an information signal at a first time of detection t_{ZCA1,1}, which is locally timestamped, of a new zero crossing of the sampled signal, and triggers a data acquisition phase at a first time T_{RA} separated from the first time of detection by a duration corresponding to the first estimate T′_{A} of the period of the electrical signal. The time of reception of this signal at the other device is also timestamped by a local timestamping means. After a duration corresponding to half the second estimate T′_{B} of the period of the electrical signal following the time of reception has elapsed, this other device triggers a phase of acquiring high-frequency events over a plurality of successive cycles having a predefined cycle duration, at a second triggering time t_{RB} determined locally and corresponding to a second time of detection of a new zero crossing of the locally sampled signal. It is then possible to determine a synchronization difference Δtₒₐ between two high-frequency events acquired, over a given cycle, by the two data acquisition devices by calculating the difference between the second triggering time t_{RB} and the first triggering time t_{RA}.

### RELATED APPLICATION

This application claims the benefit of priority from French Patent Application No. FR 23 05176, filed on May 25, 2023, the entirety of which is incorporated by reference.

### TECHNICAL FIELD

The present invention relates to the general field of monitoring the correct functioning of elements present in an electrical distribution network, in particular electrical cables, and more precisely the synchronization between at least two data acquisition devices belonging to an online monitoring system for monitoring an electrical distribution network.

### TECHNOLOGICAL BACKGROUND

One of the main problems liable to affect the operation of an electrical transmission and/or distribution network is the occurrence of partial discharges on cables, transformers, switchgear, cable junctions, etc., which may lead to their progressive degradation and, ultimately, to destructive defects.

Detecting and locating discharges may provide crucial information to the network operator regarding the state of the insulation of distribution cables during operation and of equipment in general.

Monitoring systems based on measurements at one end of a network cable, which use time domain reflectometry (TDR) and signal processing techniques, have already been proposed. However, these systems are mainly able to be used offline and have strict limits in terms of their effectiveness and their field of application.

Other known systems, referred to as online monitoring systems, are able to detect and locate events that may represent anomalies, such as partial discharges, without affecting normal operation of the network. The information relating to the progression of the phenomenon over time may prevent the occurrence of destructive defects, thus improving the reliability indices of the network and preventing the short-circuit current from impacting other equipment. As a result, such online monitoring systems contribute to one of the important aspects of the smart grid, namely making optimum use of existing assets through implementation of optimized preventive maintenance and intelligent knowledge of the state of the assets.

As shown in FIG. 1, which partially schematically illustrates one example of a mesh electrical distribution network, the principle of online monitoring consists in placing a plurality of online data acquisition devices 1 at predefined locations in the network, for example at the ends of electrical cables present in this network. In the non-limiting example of FIG. 1, three of these online data acquisition devices 1 have been shown, placed at three known locations illustrated by points A, B and C. The two devices 1 placed at points A and B are able to detect events corresponding to a partial discharge occurring at any position of a cable or equipment of the network, for example located between points A and B or even outside these points. Similarly, the two devices 1 placed at points B and C are able to detect events corresponding to a partial discharge occurring at any position of a cable or equipment of the network, for example located between points B and C, or even outside these points.

The known principle of locating a partial discharge with this type of online monitoring system is as follows: If a partial discharge 2 occurs between points A and B of the network, two corresponding pulsed signals u_{A}(t) and u_{B}(t) will propagate in opposing directions in the network. The signal u_{A}(t) is detected by the data acquisition device 1 located at point A at a time tₒₐ_{_{A}}, and the signal u_{B}(t) is detected by the data acquisition device 1 located at point B at a time tₒₐ_{_{B}}. The location Z_{PD} of the partial discharge 2 may thus be determined using the following relationship:

$${Z}_{PD} = \frac{{t}_{c} - Δ {t}_{oa}}{2 {t}_{c}} \cdot {I}_{c} with \qquad ( 1 )$$

$$Δ {t}_{oa} = {t}_{{oa}_{A}} - {t}_{{oa}_{B}} \qquad ( 2 )$$

t_{c}, the time of flight between points A and B; and
l_{c} the known length of cable separating points A and B.

In order to be able to determine the quantity Δtₒₐ, and consequently the location Z_{PD}, it is therefore necessary to synchronize the two data acquisition devices 1 located at points A and B. In other words, the times of arrival tₒₐ_{_{A}}, and tₒₐ_{_{B}} of the signals u_{A}(t) and u_{B}(t) acquired by each of the two data acquisition devices 1 must be determined in a common time frame.

As may be seen in FIG. 1, it is already known to associate each data acquisition device 1 of the monitoring system with a receiver 10 of a satellite navigation system, for example a GPS receiver 10. Each event detected by each of the data acquisition devices 1, for example the preceding signal u_{A}(t) or u_{B}(t) generated by a partial discharge, may thus be timestamped in a common reference system. This synchronization method is described for example in document WO 2021/138569. The difference between the times of arrival of the signals u_{A}(t) and u_{B}(t) at the two data acquisition devices 1, expressed in a common time frame, and consequently the location Z_{PD} of the partial discharge, may then be determined by applying relationships (1) and (2) above.

However, although the precision of the GPS may be very high, multiple factors may introduce errors, such as the effects of multiple propagation of the GPS signal, satellite localization errors, atmospheric conditions and, above all, installation difficulties. Indeed, the correct use of GPS systems involves the use of antennas that must be installed in free space to allow the satellite signal to be picked up. However, besides the fact that these antennas are expensive, many high-voltage or medium-voltage electrical distribution networks are underground distribution networks for which it is desired to minimize the need to install equipment on the surface.

Another known method, described in document WO 2004/013642 A2, consists in injecting high-frequency synchronization pulses at one of the ends of a cable with monitoring by a distribution network, using an inductive coupler. The data acquired by the monitoring systems used at both ends of the cable, generated by partial discharge pulses in the cable, thus contain both partial discharge pulses and synchronization pulses. By aligning the datasets and using the delay between the partial discharge pulse and the synchronization pulse, it is possible to obtain the location of the partial discharge. This time synchronization method uses the power cable as transmission medium for the synchronization pulses, thereby mitigating the drawback of satellite invisibility and atmospheric condition problems associated with GPS. However, the precision of this method is greatly affected by the attenuation and dispersion of the synchronization pulses propagating in the cable. This results in loss of temporal data sent via the cable.

### SUMMARY OF THE INVENTION

The aim of the present invention is to overcome the drawbacks of methods and systems for synchronizing at least two data acquisition devices of an online monitoring system for monitoring an electrical distribution network.

More precisely, one subject of the present invention is a method for synchronization between at least a first data acquisition device and a second data acquisition device of an online monitoring system for monitoring an electrical distribution network, each data acquisition device being located at a known point in the network and being configured to detect high-frequency events during data acquisition phases, the method comprising:
a first phase of estimating the period of the electrical signal travelling through the network, consisting in:
   sampling the electrical signal travelling through the network at the first data acquisition device and deducing therefrom a first estimate T′_{A} of the period of the electrical signal by detecting times of zero crossings of the sampled signal, which are locally timestamped by a first timestamping means associated with the first data acquisition device;
   sampling the electrical signal travelling through the network at the second data acquisition device and deducing therefrom a second estimate T′_{B} of the period of the electrical signal by detecting times of zero crossings of the sampled signal, which are locally timestamped by a second timestamping means associated with the second data acquisition device;
followed by a second synchronization phase, comprising the following steps:
   the first data acquisition device sending an information signal at a first time of detection t_{ZCA1,1}, which is locally timestamped, of a new zero crossing of the signal sampled at the first data acquisition device;
   the second data acquisition device locally timestamping the time of reception of said information signal;
   the first data acquisition device triggering a first phase of acquiring high-frequency events over a plurality of successive cycles having a predefined cycle duration, the first acquisition phase being triggered at a first triggering time t_{RA} determined locally by the first timestamping means and separated from the first time of detection by a duration corresponding to the first estimate T′_{A} of the period of the electrical signal;
   after a duration corresponding to half the second estimate T′_{B} of the period of the electrical signal following said time of reception has elapsed, the second data acquisition device triggering a second phase of acquiring high-frequency events over a plurality of successive cycles having a predefined cycle duration, the second acquisition phase being triggered at a second triggering time t_{RB} determined locally by the second timestamping means and corresponding to a second time of detection of a new zero crossing of the signal sampled at the second data acquisition device; and
   determining a synchronization difference Δtₒₐ between a first high-frequency event and a second high-frequency event acquired, over a given cycle, respectively by the first data acquisition device at a first acquisition time locally timestamped by the first timestamping means and by the second data acquisition device at a second acquisition time locally timestamped by the second timestamping means by calculating the difference between the second triggering time t_{RB} and the first triggering time t_{RA}.

In one possible embodiment, the predefined cycle duration for each cycle of the first data acquisition phase corresponds to the first estimate T′_{A} of the period of the electrical signal, and the predefined cycle duration for each cycle of the second data acquisition phase corresponds to the second estimate T′_{B} of the period of the electrical signal.

In one possible embodiment, the successive cycles in the first and second data acquisition phase are consecutive.

As a variant, the successive cycles in the first and second data acquisition phase are separated in pairs by a predefined spacing duration T_{S} corresponding to a predefined number of consecutive zero crossings.

In one possible embodiment, the first high-frequency event detected by the first data acquisition device and the second high-frequency event detected by the second data acquisition device over a given cycle correspond to two signals generated by the same partial discharge at a point of the network located between the first and second data acquisition devices, and the method furthermore comprises a step of calculating the location Z_{PD} of the partial discharge using the relationship

$${Z}_{PD} = \frac{{TOF}^{′} - Δ {t}_{o a}}{2 {TOF}^{′}} \cdot {I}_{c}$$

in which l_{c} is a length of cable between the first and second data acquisition devices. In particular, TOF′ denotes the time of flight between point A and point B. In particular, particularly in the above relationship, Δtₒₐ denotes the difference between the time of arrival of the partial discharge at point A locally timestamped by the first timestamping means and the time of arrival of the partial discharge at point B locally timestamped by the second timestamping means, corrected with the difference between the second triggering time t_{RB} and the first triggering time t_{RA}.

Another subject of the present invention is an online monitoring system for monitoring an electrical distribution network comprising at least a first data acquisition device and a second data acquisition device, each data acquisition device being located at a known point in the network and being configured to detect high-frequency events during data acquisition phases, the online monitoring system being characterized in that it comprises:
a first local timestamping means and a first zero crossing detection module, which are associated with the first data acquisition device, and configured to sample the electrical signal travelling through the network at the first data acquisition device and detect the times of zero crossings of the sampled signal, which are locally timestamped by the first timestamping means;
a second local timestamping means and a second zero crossing detection module, which are associated with the second data acquisition device, and configured to sample the electrical signal travelling through the network at the second data acquisition device and detect the times of zero crossings of the sampled signal, which are locally timestamped by the second timestamping means; and
synchronization means configured:
in a first estimation phase, to deduce a first estimate T′_{A} of the period of the electrical signal from times of zero crossings that are successively locally timestamped by the first timestamping means, and a second estimate T′_{B} of the period of the electrical signal from times of zero crossings that are successively locally timestamped by the second timestamping means,
and to perform a second synchronization phase, comprising the following steps:
the first data acquisition device sending an information signal at a first time of detection t_{ZCA1,1}, which is locally timestamped, of a new zero crossing of the signal sampled at the first data acquisition device;
the second data acquisition device locally timestamping the time of reception of said information signal;
the first data acquisition device triggering a first phase of acquiring high-frequency events over a plurality of successive cycles having a predefined cycle duration, the first acquisition phase being triggered at a first triggering time t_{RA} determined locally by the first timestamping means and separated from the first time of detection by a duration corresponding to the first estimate T′_{A} of the period of the electrical signal;
after a duration corresponding to half the second estimate T′_{B} of the period of the electrical signal following said time of reception has elapsed, the second data acquisition device triggering a second phase of acquiring high-frequency events over a plurality of successive cycles having a predefined cycle duration, the second acquisition phase being triggered at a second triggering time t_{RB} determined locally by the second timestamping means and corresponding to a second time of detection of a new zero crossing of the signal sampled at the second data acquisition device; and
determining a synchronization difference Δtₒₐ between a first high-frequency event and a second high-frequency event acquired, over a given cycle, respectively by the first data acquisition device at a first acquisition time locally timestamped by the first timestamping means and by the second data acquisition device at a second acquisition time locally timestamped by the second timestamping means by calculating the difference between the second triggering time t_{RB} and the first triggering time t_{RA}.

In one possible embodiment, the first timestamping means and the second timestamping means are N-bit counters, N being an integer greater than or equal to 16.

In one possible embodiment, the first timestamping means is integrated into the first data acquisition device, and/or the second timestamping means is integrated into the second data acquisition device.

In one possible embodiment, the first zero crossing detection module is integrated into the first data acquisition device, and/or the second zero crossing detection module is integrated into the second data acquisition device.

### BRIEF DESCRIPTION OF THE FIGURES

The following description provided with reference to the appended drawings, which are given by way of non-limiting example, will make it easy to understand what the invention consists of and how it may be implemented. In the appended figures:

FIG. 1, already described above, partially and schematically illustrates one example of an electrical distribution network with an online monitoring system comprising data acquisition devices that are synchronized in a known manner on the basis of a GPS navigation system;

FIG. 2 partially and schematically illustrates one example of an electrical distribution network with data acquisition devices that are synchronized according to one possible embodiment of the invention;

FIG. 3 schematically illustrates a data acquisition device in accordance with one possible embodiment according to the invention;

FIG. 4 illustrates possible steps for a synchronization method in accordance with the invention;

FIG. 5 schematically illustrates some steps of the method of FIG. 4;

FIG. 6 schematically illustrates other steps of the method of FIG. 4.

### DESCRIPTION OF EMBODIMENT(S)

In the figures, identical or equivalent elements will bear the same reference signs. The various diagrams are not to scale.

Hereinafter, the synchronization between at least two data acquisition devices of a monitoring system according to the invention will be described in the non-limiting case where the online monitoring system is configured to identify and locate partial discharges in the network. However, the synchronization principle may be extended to any online monitoring system having multiple data acquisition devices that need to be synchronized.

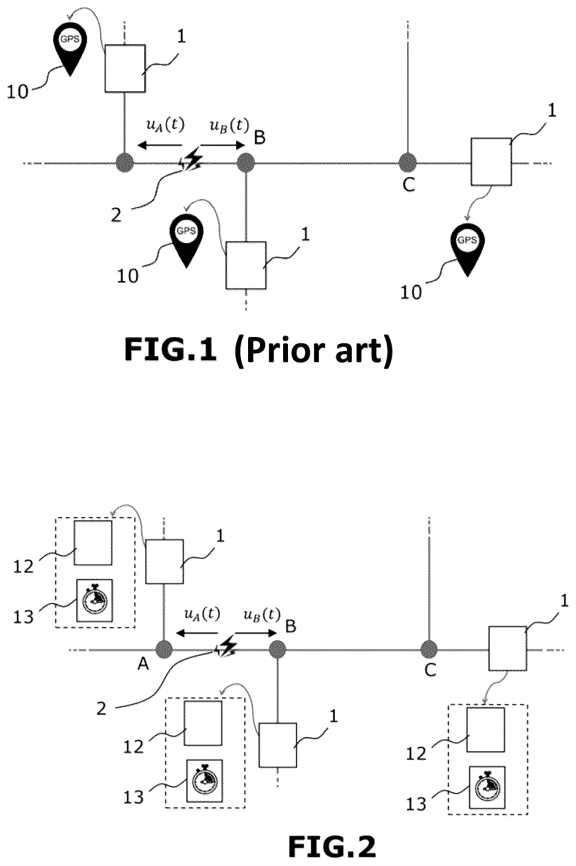

FIG. 2 partially illustrates an electrical distribution network similar to the network of FIG. 1, comprising an event monitoring system. The electrical distribution network is for example a high-voltage or medium-voltage network, composed of a plurality of electrical cables, connection accessories, equipment and/or transformers. The system comprises a plurality of acquisition devices 1 placed at various known points of the network, such as points A, B and C shown in FIG. 2. Points A, B, C where the data acquisition devices are located are preferably located at the ends of cables or of cable sections. In the non-limiting case of an underground network, the data acquisition devices 1 are preferably placed at locations that are easy to access, for example on the transformers.

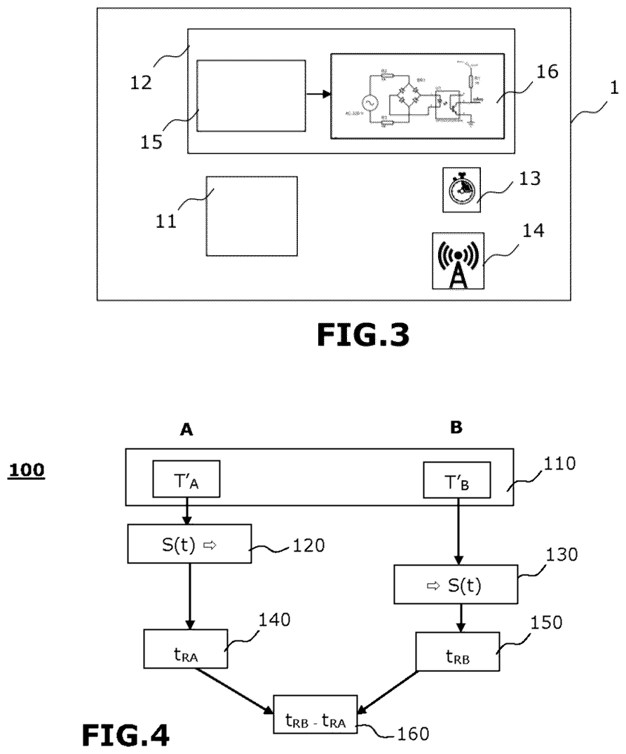

Since the devices 1 are dedicated here, without limitation, to detecting and locating partial discharges, each device 1 conventionally comprises, as illustrated schematically in FIG. 3, detection means 11 able to detect pulse events caused in the cables by the partial discharges, such as the high-frequency pulses u_{A}(t) and u_{B}(t) generated by the pulsed discharge 2 of FIG. 2. The means 11 are for example a non-invasive sensor, preferably an inductive sensor 11, located around the cable at the point where the device is located. Instead of the GPS receiver 10 of FIG. 1, the online monitoring system furthermore comprises:
a first local timestamping means 13 and a first zero crossing detection module 12, which are associated with the first data acquisition device 1, and configured to sample the electrical signal travelling through the network at the first data acquisition device 1 and detect the times of zero crossings of the sampled signal, which are locally timestamped by the first timestamping means 13;
a second local timestamping means 13 and a second zero crossing detection module 12, which are associated with the second data acquisition device 1, and configured to sample the electrical signal travelling through the network at the second data acquisition device 1 and detect the times of zero crossings of the sampled signal, which are locally timestamped by the second timestamping means 15.

The term “associated” is understood to mean that each local timestamping means 13 and/or each zero crossing detection module 12 is either electrically and functionally connected to each device 1 or integrated into each device 1, as illustrated in FIG. 3.

Each data acquisition device 1 may also advantageously comprise a mobile communication (4G or later) or Ethernet module 14, enabling it in particular to receive control signals transmitted by a remote server (not shown) contained in the online monitoring system, or to transmit information, such as the acquired data, to this server or to any other device 1 of the monitoring system. Each device 1 is also able to transmit information signals to any other device 1 contained in the monitoring system, or to receive such information signals. These information signals may be transmitted via the detection means 11, used in an active mode, the information signal then being injected into the network, in particular into the cable at the point where the device 1 is located, and recovered via the detection means of another device 1. As a variant, the information signals may be transmitted/received via the mobile communication (or Ethernet) modules 14 contained in each device 1.

Each local timestamping means 13 is preferably a precise local clock, or a 16-bit or more counter. Such a local timestamping means 13 makes it possible to locally timestamp everything that happens on each device 1, in particular detections of zero crossings, the transmission or reception of any information signal, and each event detected by the high-frequency sensor 11 at the point where the data acquisition device 1 is located, during a data acquisition phase.

Each zero crossing detection module 12 comprises a low-frequency sensor 15 able to sample the electrical sinusoidal signal travelling through the network at the fundamental frequency of 50 Hz or 60 Hz depending on the country of the point (A, B or C) where the device 1 in question is located, and a zero crossing detection circuit 16 receiving the signal sampled by the low-frequency sensor 15. The low-frequency sensor 15 is preferably a non-invasive sensor, for example a contactless ELF magnetometer or an inductive ELF sensor (ELF standing for “extremely low frequency”). Low-frequency capacitive sensors may nevertheless be envisaged. The circuit 16 may implement any known zero crossing detection algorithm. The zero crossing detector circuit 16 may be any known comparator circuit that makes it possible to detect the voltage of the sampled signal when it changes from the positive level to the negative level and from the negative level to the positive level.

Finally, the online monitoring system also comprises time synchronization means configured to implement the steps of a synchronization method in accordance with the invention, which will now be explained.

The synchronization method used by the data acquisition devices 1, in accordance with the present invention, is illustrated in FIG. 4. For the sake of simplification, the explanation is given with regard to the two devices 1 located at points A and B, but may easily be extended to all data acquisition devices 1 present in the electrical network:

The synchronization method 100 starts with a phase of estimating the period of the electrical signal passing through the network, carried out at each data acquisition device 1, and in particular at each zero crossing detection module 12. More specifically, the estimation phase 110 consists in:
on the one hand, sampling the electrical signal travelling through the network at the first data acquisition device 1, located at point A, and deducing therefrom a first estimate T′_{A} of the period of the electrical signal by detecting times of zero crossings of the sampled signal, which are locally timestamped by a first timestamping means 13 associated with the first data acquisition device 1;
on the other hand, sampling the electrical signal travelling through the network at the second data acquisition device 1, located at point B, and deducing therefrom a second estimate T's of the period of the electrical signal by detecting times of zero crossings of the sampled signal, which are locally timestamped by a second timestamping means 13 associated with the second data acquisition device.

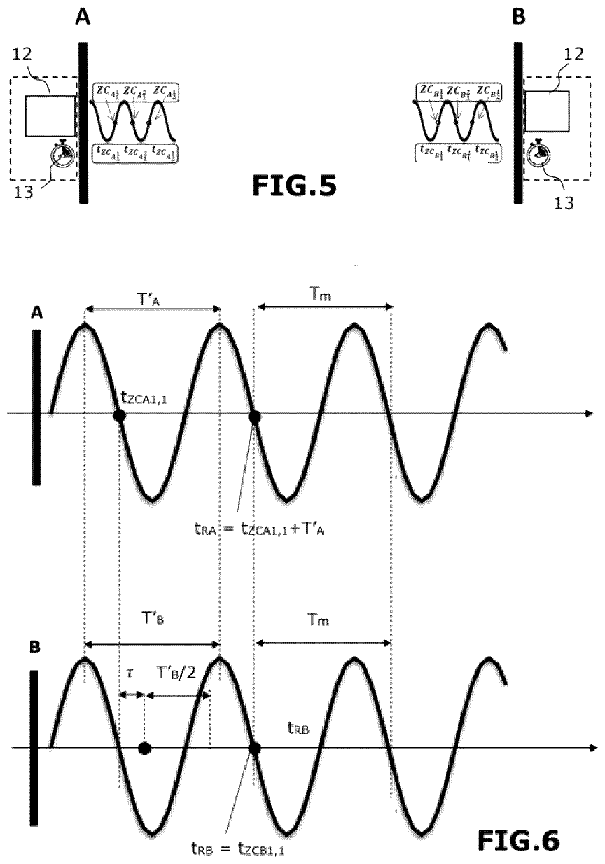

As illustrated schematically in FIG. 5, and taking into account the fact that the sampled signal corresponds to the sinusoidal electrical signal at the fundamental frequency of the electrical network (that is to say at 50 Hz or 60 Hz depending on the country), this signal crosses zero twice during each signal period. In other words, each zero crossing detection module will be able to detect a pair of zero crossings for each period of the periodic signal sampled at the device 1 located at point A, respectively of the periodic signal sampled at the device 1 located at point B. Each device will also be able to locally timestamp each detection of a zero crossing via its timestamping means 13. If:

$$\{ ( {ZC}_{{A}_{1}^{1}} , {ZC}_{{A}_{1}^{2}} ) , ( {ZC}_{{A}_{2}^{1}} , Z {C}_{{A}_{2}^{2}} ) , … , ( {ZC}_{{A}_{M}^{1}} , Z {C}_{{A}_{M}^{2}} ) \} ,$$

$$respectively \{ ( {ZC}_{{B}_{1}^{1}} , Z {C}_{{B}_{1}^{2}} ) , ( Z {C}_{{B}_{2}^{1}} , Z {C}_{{B}_{2}^{2}} ) , … , ( Z {C}_{{B}_{M}^{1}} , Z {C}_{{B}_{M}^{2}} ) \}$$

are used to denote M successive pairs of zero crossings detected by the device 1 located at point A, respectively at point B, and

$$\{ ( {t}_{{ZC}_{{A}_{1}^{1}}} , {t}_{{ZC}_{{A}_{1}^{2}}} ) , ( {t}_{{ZC}_{{A}_{2}^{1}}} , {t}_{{ZC}_{{A}_{2}^{2}}} ) , … , ( {t}_{{ZC}_{{A}_{M}^{1}}} , {t}_{{ZC}_{{A}_{M}^{2}}} ) \} ,$$

$$respectively \{ ( {t}_{{ZC}_{{B}_{1}^{1}}} , {t}_{{ZC}_{{B}_{1}^{2}}} ) , ( {t}_{{ZC}_{{B}_{2}^{1}}} , {t}_{{ZC}_{{B}_{2}^{2}}} ) , … , ( {t}_{{ZC}_{{B}_{M}^{1}}} , {t}_{{ZC}_{{B}_{M}^{2}}} ) \}$$

are used to denote the pairs of associated times obtained by local timestamping via the timestamping means 13 associated with the data acquisition device 1 located at point A, respectively at point B, the estimate T′_{A}, respectively T′_{B}, of the period of the periodic signal is calculated using the relationship:

$${T}_{A}^{′} = 2 \times {\sum }_{i = 1}^{M} ( {t}_{{ZC}_{{A}_{i}^{2}}} - {t}_{{ZC}_{{A}_{i}^{1}}} )$$

$$respectively {T}_{B}^{′} = 2 \times {\sum }_{i = 1}^{M} ( {t}_{{ZC}_{{B}_{i}^{2}}} - {t}_{{ZC}_{{B}_{i}^{1}}} )$$

The larger the integer M, the more this does away with fluctuations that could affect the periodic signal due to overloading or the presence of equipment in the network. The integer M may for example be equal to 100, or even 200 or 300.

Once each device has been able to locally estimate the period T′_{A} or T′_{B} of the sampled periodic signal, the method 100 continues with a second synchronization phase, comprising the following steps (see FIGS. 4 and 6 together):

The data acquisition device 1 located at point A sends, in a step 120, an information signal s(t) at a first time of detection t_{ZCA1,1}, which is locally timestamped, of a new zero crossing of the signal sampled at this data acquisition device 1. As seen above, this signal s(t) may be sent via any transmission channel (by the network itself by injecting the signal into the cable or through cellular communication or via Ethernet). The signal s(t) may be of any type.

In a step 130, the information signal s(t) is received by the data acquisition device 1 located at point B, after a duration corresponding to the time of flight τ between the two points A and B. It should be noted that this time of flight τ is generally of the order of one microsecond for a maximum distance of around 15 km separating the two points A and B. In this step 130, the time of reception of this information signal s(t) is locally timestamped by the local timestamping means 13 associated with this device 1.

In a step 140, the triggering data acquisition device 1 located at point A triggers a first phase of acquiring high-frequency events by way of its sensor 11, over a plurality of successive cycles having a predefined cycle duration Tₘ, the first acquisition phase being triggered at a first triggering time t_{RA} determined locally by the first local timestamping means 13 and separated from the first time of detection t_{ZCA1,1} by a duration corresponding to the first estimate T′_{A} of the period of the electrical signal.

Moreover, after a duration corresponding to T′_{B}/2 following the time of reception of the signal s(t) has elapsed, the data acquisition device 1 located at point B triggers, in a step 150, a second phase of acquiring high-frequency events by way of its own sensor 11, over a plurality of successive cycles having a predefined cycle duration, the second acquisition phase being triggered at a second triggering time t_{RB} determined locally by the second timestamping means 13 and corresponding to a second time of detection of a new zero crossing of the signal sampled at the second data acquisition device 1.

In one particularly advantageous embodiment, the predefined cycle duration for each cycle of the first data acquisition phase corresponds to the first estimate T′_{A} of the period of the electrical signal, and the predefined cycle duration for each cycle of the second data acquisition phase corresponds to the second estimate T′_{B} of the period of the electrical signal. As a result, the cycle durations for the two phases match.

As shown in FIG. 6, the triggering times T_{RA} and T_{RB}, although they are measured locally by each timestamping means 13, are supposed to coincide in a common time frame.

As a result, it is possible, in a determination step 160, to determine a synchronization difference Δtₒₐ between a first high-frequency event and a second high-frequency event acquired, over a given cycle, respectively by the data acquisition device 1 located at point A, at a first acquisition time locally timestamped by its own timestamping means 13, and by the second data acquisition device 1 located at point B, at a second acquisition time locally timestamped by its own timestamping means 13, by simply calculating the difference between the second triggering time t_{RB} and the first triggering time t_{RA}. This calculation may be carried out locally (for example on the first device 1 located at point A) or in a centralized manner on the remote server.

In one possible embodiment, the successive cycles in the first and second data acquisition phase are separated in pairs by a predefined spacing duration T_{S} corresponding to a predefined number of consecutive zero crossings.

As a variant, the successive cycles in the first and second data acquisition phase are consecutive, which is tantamount to stating that the spacing duration T_{S} is zero.

In all cases, a cycle (n+1) for the device 1 located at point A, respectively at point B, starts at a time

$${t}_{{R}_{{A}_{n + 1}}} , respectively {t}_{{R}_{{B}_{n + 1}}} ,$$

which may be expressed as a function of the preceding cycle n, using the relationship:

$${t}_{{R}_{{A}_{n + 1}}} = {t}_{{oa}_{{A}_{n}}} + {T}_{m} + {T}_{s} , respectively {t}_{{R}_{{B}_{n + 1}}} = {t}_{{oa}_{{B}_{n}}} + {T}_{m} + {T}_{s}$$

such that, for each cycle n, the following relationship is retained

$$Δ {t}_{o {a}_{n}} = {t}_{{oa}_{{B}_{n}}} - {t}_{{oa}_{{A}_{n}}} = {t}_{{R}_{{B}_{n + 1}}} - {t}_{{R}_{{A}_{n + 1}}}$$

Any high-frequency event liable to be detected by the detection means 11 of the device 1 located at point A or of the device 1 located at point B during data acquisition phases will consequently be able to be timestamped first locally, via the local timestamping means 13, and then in a common reference base by virtue of the knowledge of the synchronization difference Δtₒₐ between the two data acquisition devices 1.

In the non-limiting case where the data acquisition devices 1 are dedicated to detecting high-frequency events corresponding to signals u_{A}(t) and u_{B}(t) generated by the same partial discharge 2, the method furthermore comprises a step (not shown) of calculating the location Z_{PD} of the partial discharge using the relationship

$${Z}_{PD} = \frac{{TOF}^{′} - Δ {t}_{oa}}{2 {TOF}^{′}} \cdot {I}_{c}$$

in which l_{c} is a length of cable between the first and second data acquisition devices (1). In particular, TOF′ denotes the time of flight between point A and point B. In particular, in the above relationship, Δtₒₐ denotes the difference between the time of arrival of the partial discharge at point A and the time of arrival of the partial discharge at point B, corrected with the difference between the second triggering time t_{RB} and the first triggering time t_{RA}. In particular, this is apparent from the passage in paragraph [0007] and the passage in paragraph [42].

This calculation step may for example be carried out on the remote central server.

Steps 110 to 160 are preferably repeated periodically (for example one or more times a day) so as to compensate for drifts that may affect the network, such as temperature changes, overloads, and/or dispersion in the counters 13.

1. A method for synchronization between at least a first data acquisition device and a second data acquisition device of an online monitoring system for monitoring an electrical distribution network, each data acquisition device being located at a known point in the network and being configured to detect high-frequency events during data acquisition phases, the method comprising:
a first phase of estimating the period of the electrical signal travelling through the network, including:
sampling the electrical signal travelling through the network at the first data acquisition device and deducing therefrom a first estimate T′_{A} of the period of the electrical signal by detecting times of zero crossings of the sampled signal, which are locally timestamped by a first timestamping means associated with the first data acquisition device;
sampling the electrical signal travelling through the network at the second data acquisition device and deducing therefrom a second estimate T′_{B} of the period of the electrical signal by detecting times of zero crossings of the sampled signal, which are locally timestamped by a second timestamping means associated with the second data acquisition device;
followed by a second synchronization phase, including the following steps:
the first data acquisition device sending an information signal at a first time of detection t_{ZCA1,1}, which is locally timestamped, of a new zero crossing of the signal sampled at the first data acquisition device;
the second data acquisition device locally timestamping the time of reception of said information signal;
the first data acquisition device triggering a first phase of acquiring high-frequency events over a plurality of successive cycles having a predefined cycle duration, the first acquisition phase being triggered at a first triggering time t_{RA} determined locally by the first timestamping means and separated from the first time of detection by a duration corresponding to the first estimate T′_{A} of the period of the electrical signal;
after a duration corresponding to half the second estimate T′_{B} of the period of the electrical signal following said time of reception has elapsed, the second data acquisition device triggering a second phase of acquiring high-frequency events over a plurality of successive cycles having a predefined cycle duration, the second acquisition phase being triggered at a second triggering time t_{RB} determined locally by the second timestamping means and corresponding to a second time of detection of a new zero crossing of the signal sampled at the second data acquisition device; and
determining a synchronization difference Δtₒₐ between a first high-frequency event and a second high-frequency event acquired, over a given cycle, respectively by the first data acquisition device at a first acquisition time locally timestamped by the first timestamping means and by the second data acquisition device at a second acquisition time locally timestamped by the second timestamping means by calculating the difference between the second triggering time t_{RB} and the first triggering time t_{RA}.

2. The method according to claim 1, wherein the predefined cycle duration for each cycle of the first data acquisition phase corresponds to the first estimate T′_{A} of the period of the electrical signal, and the predefined cycle duration for each cycle of the second data acquisition phase corresponds to the second estimate T′_{B} of the period of the electrical signal.

3. The method according to claim 1, wherein the successive cycles in the first and second data acquisition phase are consecutive.

4. The method according to claim 1, wherein the successive cycles in the first and second data acquisition phase are separated in pairs by a predefined spacing duration T_{S} corresponding to a predefined number of consecutive zero crossings.

5. The method according to claim 1, wherein the first high-frequency event detected by the first data acquisition device and the second high-frequency event detected by the second data acquisition device over a given cycle correspond to two signals generated by the same partial discharge at a point of the network located between the first and second data acquisition devices, and in that the method furthermore comprises a step of calculating the location Z_{PD} of the partial discharge using the relationship
$${Z}_{PD} = \frac{{TOF}^{′} - Δ {t}_{oa}}{2 {TOF}^{′}} \cdot {I}_{c}$$
in which l_{c} is a length of cable between the first and second data acquisition devices (1).

6. An online monitoring system for monitoring an electrical distribution network having at least a first data acquisition device and a second data acquisition device, each data acquisition device being located at a known point in the network and being configured to detect high-frequency events during data acquisition phases, the online monitoring system comprising:
a first local timestamping means and a first zero crossing detection module, which are associated with the first data acquisition device, and configured to sample the electrical signal travelling through the network at the first data acquisition device and detect the times of zero crossings of the sampled signal, which are locally timestamped by the first timestamping means;
a second local timestamping means and a second zero crossing detection module, which are associated with the second data acquisition device, and configured to sample the electrical signal travelling through the network at the second data acquisition device and detect the times of zero crossings of the sampled signal, which are locally timestamped by the second timestamping means; and
synchronization means configured:
in a first estimation phase, to deduce a first estimate T′_{A} of the period of the electrical signal from times of zero crossings that are successively locally timestamped by the first timestamping means, and a second estimate T′_{B} of the period of the electrical signal from times of zero crossings that are successively locally timestamped by the second timestamping means,
and to perform a second synchronization phase, comprising the following steps:
the first data acquisition device sending an information signal at a first time of detection t_{ZCA1,1}, which is locally timestamped, of a new zero crossing of the signal sampled at the first data acquisition device;
the second data acquisition device locally timestamping the time of reception of said information signal;
the first data acquisition device triggering a first phase of acquiring high-frequency events over a plurality of successive cycles having a predefined cycle duration, the first acquisition phase being triggered at a first triggering time t_{RA} determined locally by the first timestamping means and separated from the first time of detection by a duration corresponding to the first estimate T′_{A} of the period of the electrical signal;
after a duration corresponding to half the second estimate T′_{B} of the period of the electrical signal following said time of reception has elapsed, the second data acquisition device triggering a second phase of acquiring high-frequency events over a plurality of successive cycles having a predefined cycle duration, the second acquisition phase being triggered at a second triggering time t_{RB} determined locally by the second timestamping means and corresponding to a second time of detection of a new zero crossing of the signal sampled at the second data acquisition device; and
determining a synchronization difference Δtₒₐ between a first high-frequency event and a second high-frequency event acquired, over a given cycle, respectively by the first data acquisition device at a first acquisition time locally timestamped by the first timestamping means and by the second data acquisition device at a second acquisition time locally timestamped by the second timestamping means by calculating the difference between the second triggering time t_{RB} and the first triggering time t_{RA}.

7. The system according to claim 6, wherein the first timestamping means and the second timestamping means are N-bit counters, N being an integer greater than or equal to 16.

8. The system according to claim 6, wherein the first timestamping means is integrated into the first data acquisition device, and/or the second timestamping means is integrated into the second data acquisition device.

9. The system according to claim 6, wherein the first zero crossing detection module is integrated into the first data acquisition device, and/or the second zero crossing detection module is integrated into the second data acquisition device.
